(19) United States
(12) Patent Application Publication
(10) Pub. No.: US 2006/0243482 A1
(43) Pub. Date: Nov. 2, 2006

(54) Circuit board structure and method for fabricating the same

(76) Inventors: E-Tung Chou, Hsin-chu (TW); Wen-Shien Huang, Hsin-chu (TW)

Correspondence Address: SAWYER LAW GROUP LLP, P O BOX 51418, PALO ALTO, CA, 94303, US

(21) Appl. No.: 11/411,392

(22) Filed: Apr. 26, 2006

(30) Foreign Application Priority Data
Apr. 27, 2005 (TW) 094113379

(51) Int. Cl. H05K 1/11

(52) U.S. Cl. 174/262; 205/125; 174/264; 174/266

(57) ABSTRACT

A circuit board structure and a method for fabricating the same are proposed in the present invention. Firstly, a core layer covered with a first metal layer on a surface thereof is provided. Also, the core layer is formed with at least one through hole penetrating therethrough. A second metal layer is formed on a surface of the core layer and a wall of the through hole, such that a plated through hole can be formed penetrating through the core layer. Then, a filling material is filled in the plated through hole. A surface of the second metal layer is thinned to expose the first metal layer. A resist layer is formed on the first metal layer on the surface of the core layer by a circuit patterning process, such that a patterned circuit layer can be subsequently formed by an electrical plating process. Moreover, the circuit layer formed on the surface of the core layer can be electrically connected by the means of the plated through hole. By such arrangement, fabrication of fine circuits can be provided to achieve the development of a circuit board requiring fine circuits.

The present invention relates to a circuit board structure and a method for fabricating the same, and more particularly, to a method for fabricating a circuit board structure with fine circuits by pattern plating.

### BACKGROUND OF THE INVENTION

Along with the blooming development of electronic industry, electronic products are gradually becoming more multi-functional and highly efficient. In order to meet requirements for a micro processor, a chip set and a graphic chip, a circuit board arranged with traces also needs to improve functions including chip signal transmission, bandwidth improvement and resist control, so as to achieve the development of a package with high input/output (I/O) connections.

In order to meet requirements such as miniaturization, multi-function, high speed and multiplexing for a semiconductor package, a circuit board is gradually developed with fine circuits and small conductive vias. The circuit size such as a line width, a circuit space and an aspect ratio in the current circuit board fabricating method has reduced from traditional 100 μm to less than 30 μm. Also, finer circuits are likely to be developed in the near future.

FIG. 1A to FIG. 1E are cross-sectional views of a method for fabricating a prior-art circuit board. Referring to FIG. 1A, firstly, a metal laminated core plate 100 such as resin coated copper (RCC) 101 is provided. Then, a plurality of through holes 102 is formed penetrating through the metal laminated core plate. Referring to FIG. 1B, a metal layer 103 is deposited on a surface of the core plate 100 and a wall of the through hole 102 by a copper electroplating process, such that a plated through hole 102a is formed to electrically connect the metal layers 103 formed on an upper surface and a lower surface of the core plate 100. Referring to FIG. 1C, a conductive or a non-conductive filling material 11 (such as an insulating ink or a copper conductive paste) is filled in a remaining space of the plated through hole 102a. Referring to FIG. 1D, an unwanted part of the filling material 11 is removed by brush polishing. Referring to FIG. 1E, the resin coated copper 101 and the metal layer 103 formed on the two surfaces of the core plate 100 are performed with a circuit patterning process, so as to form a circuit board structure having a double-layered circuits 104.

Referring to the foregoing method for fabricating the prior-art circuit board, a conductive layer such as a metal material (not shown in the figure) is formed on the surface of the core plate 100 and the wall of the through hole 102, such that the conductive layer can serve as a current conductive path for forming the metal layer 103 on the resin coated copper 101 formed on the surface of the core plate 100 and the wall of the through hole 102 by an electroplating process. Then, the filling material 11 is filled in the through hole 102 and the unwanted part of the filling material 11 is removed. Afterwards, a circuit patterning process is performed by an etching method. Accordingly, a resist layer such as a dry film or photo-resist (not shown in the figure) is formed on the metal layer 103 on the surface of the core plate 100 before being performed with a circuit patterning process by exposure and development processes, such that the resist layer is formed with a plurality of openings to expose the metal layer 103 formed on the surface of the core plate 100. Then, the part of the metal layer 103 which is not covered by the resist layer is removed by a subtractive process such as etching, so as to form the patterned circuit 104.

Referring to the foregoing fabricating method, however, when forming the plated through hole (PTH), the metal layer 103 is firstly formed on the wall of the through hole 102 of the core plate 100. Thus, the metal layer 103 is simultaneously formed on the resin coated copper 101 on the surface of the core plate 100, such that the thickness of the circuit 104 which is subsequently formed on the surface of the core plate 100 by the etching process is increased. In order to completely etch the metal layer 103 and the resin coated copper 101, an increase in the thickness of the circuit 104 will also increase the time requiring for the etching process. As side etching is usually occurred during the etching process, the circuit needs to have a certain width to prevent from being cracked due to an excessively long etching process, such that fabrication of circuits with a high density cannot be provided. Furthermore, the circuit of the circuit board formed by the subtractive process such as etching is less able to meet the requirement of fine circuits when comparing to a patterned circuit structure formed by an electroplating process.

Packages characterized with a reduced integrated circuit (IC) area, a high density and multiple leads have become the mainstream of the packaging market. Also, the method for fabricating the circuit board is about 20% to 50% of the packaging cost. Therefore, as the integrated circuit (I/C) fabrication of the semiconductor chip has reduced to 0.09 μm and the packaging size is also continuously miniaturized, the problem to be solved herein is to provide a circuit board with fine circuits and a high circuit density while the production cost is not dramatically increased.

### SUMMARY OF THE INVENTION

In light of the above prior-art drawbacks, a primary objective of the present invention is to provide a circuit board structure and a method for fabricating the same, by which the problems that the thickness of a circuit formed by a subsequent etching process is increased and fabrication of fine circuits become difficult when forming a metal layer on the wall of a though hole during a method for fabricating a prior-art circuit board can be solved.

Another objective of the present invention is to provide a circuit board structure and a method for fabricating the same, by which fine circuits are formed by a build-up method using an electroplating process instead of a subtractive method using an etching process.

In accordance with the above and other objectives, the present invention proposes a circuit board structure and a method for fabricating the same. Firstly, a core layer covered with a first metal layer on a surface thereof is provided. Also, the core layer is formed with at least one through hole penetrating therethrough. A second metal layer is formed on a surface of the core layer and a wall of the through hole, such that a plated through hole can be formed. Then, a filling material is filled in the plated through hole. A surface of the second metal layer is thinned to expose the first metal layer. A resist layer is formed on the first metal layer on the surface of the core layer, and the resist layer is subsequently performed with a circuit patterning process to form openings, such that the first metal layer is partially exposed. A pattern plating process is performed to form a patterned circuit layer on the first metal layer exposed from the opening of the resist layer. Lastly, the resist layer and the first metal layer covered by the resist layer are removed. Furthermore, an insulating protective layer can be formed on the surface of the core layer formed with the circuit layer, and the insulating protective layer can be formed with openings to expose parts of the circuit layer which serve as electrical conductive pads. Thus, a double-layered circuit board which is able to electrically connect an external device can be fabricated. Alternatively, the core layer formed with the circuit layer can be used as a core circuit board, such that a multi-layered circuit board can be fabricated by a build-up method.

According to the foregoing method, the present invention also proposes a circuit board structure, comprising of a core layer having at least one through hole, wherein the core layer is a resin coated copper film or a multi-layered circuit board completed with initial processes, the multi-layered circuit board being laminated with an insulating layer having a metal layer on a surface thereof; a circuit layer formed on the surface of the core layer, wherein a plated through hole is formed in the through hole of the core layer to electrically connect the circuit layer formed on the surface of the core layer; and a filling material for filling the plated through hole, wherein the filling material is positioned lower than the circuit layer.

Referring to the foregoing method for fabricating the circuit board structure, before performing the pattern plating process, the metal layer formed on the surface of the core layer can be initially thinned to form a predetermined thickness for subsequently forming patterned fine circuits.

When comparing to the prior-art technique, in the method for fabricating the circuit board structure proposed by the present invention, the metal layer formed on the surface of the core layer and the wall of the through hole in the core layer can serve as a current conductive path for the subsequent pattern plating process and provide the plated through hole for electrical connection. The patterned circuit layer can be directly formed on the surface of the core layer by the pattern plating process, so as to fabricate fine circuits. Therefore, the problem that the thickness of the circuit which is subsequently formed by an etching process is increased when the metal layer is formed on the wall of the through hole during the formation of a plated through hole using the prior-art technique can be solved, such that fabrication of fine circuits can be achieved and the circuit accuracy will be no longer limited by the etching process.

### BRIEF DESCRIPTION OF THE DRAWINGS

The present invention can be more fully understood by reading the following detailed description of the preferred embodiments, with reference made to the accompanying drawings, wherein:

FIG. 1A to FIG. 1E are cross-sectional views of a method for fabricating a prior-art circuit board; and

FIG. 2A to FIG. 2H are cross-sectional views of a circuit board structure and a method for fabricating the same according to a preferred embodiment of the present invention.

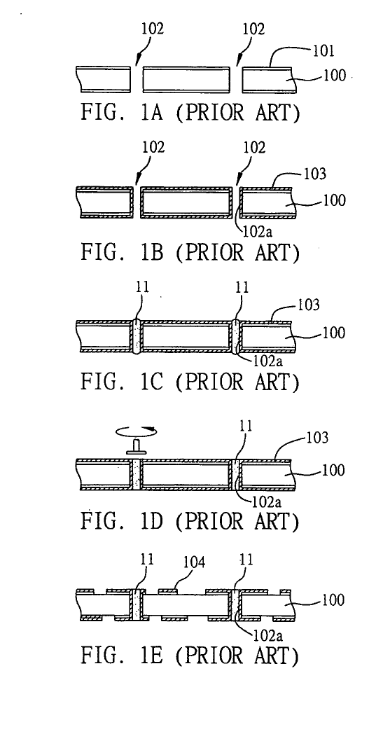

### DETAILED DESCRIPTION OF THE EMBODIMENTS

The present invention relates generally to a circuit board structure and a method for fabricating the same, and more particularly, to a method for fabricating a circuit board structure with fine circuits by pattern plating. The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

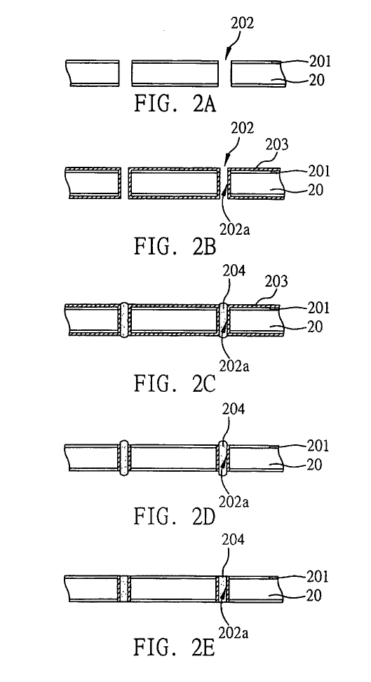

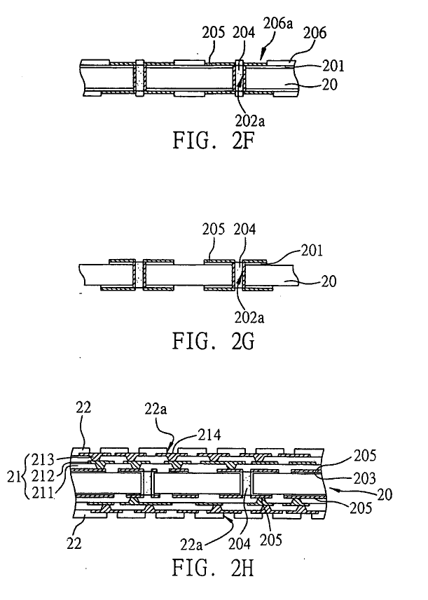

FIG. 2A to FIG. 2H are cross-sectional views of a circuit board structure and a method for fabricating the same according to a preferred embodiment of the present invention. What needs to be concerned is that these drawings are simplified schematic diagrams, and thus only structures relevant to the present invention are illustrated. Also, these structures are not drawn according to actual amounts, shapes and dimensions. Actually, the amount, shape and dimension are an optional design and the arrangements of the structures may be very complex in reality.

Referring to FIG. 2A, a core layer 20 is firstly provided. The core layer 20 can be a resin coated copper (RCC) film covered with a first metal layer 201 on a surface thereof, or alternatively, can be a multi-layered circuit board completed with initial processes which is laminated with an insulating layer having a metal layer on a surface thereof. Further, the core layer 20 can be formed with at least a through hole 202 by mechanical or laser drilling.

Referring to FIG. 2B, a thin metal layer (not shown in the figure) is formed on a wall of the through hole 202 and the surface of the core layer 20 by a method such as physical vapor deposition (PVD), chemical vapor deposition (CVD), electroless plating or chemical deposition. Then, a second metal layer 203 with a sufficient thickness is formed by an electroplating process, and a plated through hole 202a is formed in the through hole 202. The material of the second metal layer 203 is selected depending on practical requirements. As copper is an available material used in the electroplating process and is cost-effective, the second metal layer can be made of copper but is not limited by copper.

Referring to FIG. 2C, a conductive or non-conductive filling material 204 (such as a filling material comprising copper paste or an ink resin) is used to fill the plated through hole 202a formed with the second metal layer 203. In the present figure, the filling material 204 is protruded from the core layer 20 to provide sufficient amount to tightly fill the plated through hole 202a. However, the filling material 204 can be effectively filled in the plated through hole 202a without being protruded from the surface of the core layer 20 (not shown in the figure).

Referring to FIG. 2D, the second metal layer 203 formed on the surface of the core layer 20 is thinned by a thinning process such as a surface uniform etching process (SUEP), such that the second metal layer 203 is removed from the surface of the core layer 20 to expose the first metal layer 201. Thus, the exposed metal layer 201 can serve as a current conductive path for a subsequent electrical plating process, such that a patterned circuit layer can be formed on the first metal layer 201 on the surface of the core layer 20 by the electrical plating process. After performing the thinning process, the thick second metal layer 203 can be removed to prevent the formation of an excessive thick circuit, so that fine circuits can be fabricated.

Referring to FIG. 2E, two ends of the filling material 204 protruded from the through hole 202 on the surface of the core layer 20 are removed by a brush polishing process, such that an upper surface and a lower surface of the core layer can be made flat to provide reliability for subsequent processes.

Referring to FIG. 2F, a resist layer 206 is formed on the first metal layer 201 on the surface of the core layer 20, and the resist layer 206 is subsequently performed with a circuit patterning process to form openings 206a, such that the first metal layer 201 is partially exposed. Then, the core layer 20 is performed with a pattern plating process, such that a patterned circuit layer 205 is formed on the first metal layer 201 exposed from the opening 206a of the resist layer 206. Also, the circuit layer 205 formed on the surface of the core layer 20 is electrically connected by the plated through hole 202a. The resist layer 206 can be a dry film or liquid photo-resist and can be patterned by exposure and development processes, such that the resist layer 206 is formed with the opening 206a to partially expose the first metal layer 201 formed on the surface of the core layer 20. Further, the first metal layer 201 can serve as a current conductive path, such that the patterned circuit layer 205 can be formed on the first metal layer 201 exposed from the opening 206a of the resist layer 206 by the electrical plating process.

Referring to FIG. 2G, the resist layer 206 and the first metal layer 201 which is not covered by the circuit layer 205 are removed, so as to form a circuit board structure with fine circuits.

Referring to FIG. 2H, a circuit build-up structure 21 can be formed on the surface of the core layer 20 and the circuit layer 205. The circuit build-up structure 21 comprises a dielectric layer 211, a circuit layer 212 deposited on the dielectric layer 211, and a conductive structure 213 formed in the dielectric layer 211. The conductive structure 213 is electrically connected to the circuit layer 205 formed on the surface of the core layer 20. Further, an insulating protective layer 22 is formed on an outside surface of the circuit build-up structure 21. Also, the insulating protective layer 22 is formed with a plurality of openings 22a penetrating therethrough to expose the parts of the circuit layer 212 which can serve as electrical conductive pads 214. In the present embodiment, the insulating protective layer 22 can be formed on the surface of the circuit build-up structure 21 by printing or spin-coating, and subsequently formed with the opening 22a by a circuit patterning process such as exposure and development processes, such that the electrical conductive pad 214 of the circuit layer 205 can be exposed. Moreover, a double metal protection layer such as nickel/gold (not shown in the figure) can be formed on the electrical conductive pad 214, so as to form a multi-layered circuit board. Then, the circuit board can be mounted with semiconductor elements and electrically connected to an external device.

Accordingly, referring to the method for fabricating the circuit board structure proposed in the present invention, a core layer covered with a first metal layer on a surface thereof is provided. Also, the core layer is formed with at least one through hole penetrating therethrough. A second metal layer with a certain thickness is formed on a surface of the core layer having the first metal layer and on a wall of the through hole. Afterwards, the through hole is filled with a filling material to form a plated through hole. Subsequently, the second metal layer formed on the surface of the core layer is thinned to expose the first metal layer. Thus, the first metal layer can serve as a current conductive path. Also, a resist layer can be formed on the first metal layer by a circuit patterning process, such that a patterned circuit can be directly formed on the metal layer on the surface of the core layer by an electrical plating process. Additionally, the circuit formed on the surface of the core layer can be electrically connected by the means of the plated through hole.

In comparison to the prior-art technique, the method for fabricating the circuit board structure proposed in the present invention is able to directly form a patterned circuit layer on the surface of the core layer by an electrical plating process as the metal layer on the surface of the core layer can serve as a current conductive path, such that fine circuits can be fabricated. Therefore, the problem that the thickness of the circuit which is subsequently formed by an etching process is increased when the metal layer is formed on the wall of the through hole during the formation of a plated through hole using the prior-art technique can be solved, such that fabrication of fine circuits can be achieved.

The present invention also proposes a circuit board structure fabricated using the foregoing method, comprising of: a core layer 20 having at least one through hole 202, wherein the core layer is a resin coated copper film or an insulating plate, or a multi-layered circuit board completed with initial processes, the multi-layered circuit board being laminated with an insulating layer having a metal layer on a surface thereof; a circuit layer 205 formed on the surface of the core layer 20, wherein a plated through hole 202a is formed in the through hole 202 of the core layer 20 to electrically connect the circuit layer 205 formed on the surface of the core layer 20; and a filling material 204 for filling the plated through hole 202a, wherein the filling material 204 is positioned lower than the circuit layer 205.

Moreover, a circuit build-up structure 21 can be formed on the surface of the core layer 20 and the circuit layer 205. The circuit build-up structure 21 comprises a dielectric layer 211, a circuit layer 212 deposited on the dielectric layer 211, and a conductive structure 213 formed in the dielectric layer 211. Also, the conductive structure 213 is electrically connected to the circuit layer 205 formed on the surface of the core layer 20. Further, an insulating protective layer 22 is formed on an outside surface of the circuit build-up structure 21. The insulating protective layer 22 is formed with a plurality of openings 22a penetrating therethrough to expose the parts of the circuit layer 212 which can serve as electrical conductive pads 214, so as to form a multi-layered circuit board structure.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A method for fabricating a circuit board structure, comprising steps of:
providing a core layer covered with a first metal layer on a surface thereof, wherein the core layer is formed with at least one through hole penetrating therethrough;
forming a second metal layer on a surface of the core layer and a wall of the through hole, such that a plated through hole can be formed to electrically connect the first metal layer to the second metal layer formed on the surface of the core layer, the through hole being filled with a filling material;
removing the second metal layer formed on the surface of the core layer to expose the first metal layer;
forming a resist layer on the first metal layer on the surface of the core layer and patterning the resist layer, such that openings are formed penetrating though the resist layer to partially expose the first metal layer;
forming a patterned circuit layer on the first metal layer exposed from the opening of the resist layer by performing an electrical plating process, wherein the circuit layer formed on the surface of the core layer is electrically connected by the means of the plated through hole; and
removing the resist layer and the first metal layer covered by the resist layer.

2. The method for fabricating the circuit board structure of claim 1, further comprising a step of forming a circuit build-up structure on the surface of the core layer having the circuit layer.

3. The method for fabricating the circuit board structure of claim 2, wherein the circuit build-up structure further comprises a dielectric layer, a circuit layer deposited on the dielectric layer, and a conductive structure formed in the dielectric layer.

4. The method for fabricating the circuit board structure of claim 3, wherein the conductive structure is electrically connected to the circuit layer formed on the surface of the core layer.

5. The method for fabricating the circuit board structure of claim 4, further comprising a step of forming an insulating protective layer on an outside surface of the circuit build-up structure.

6. The method for fabricating the circuit board structure of claim 5, wherein the insulating protective layer is formed with a plurality of openings to expose parts of the circuit layer which can serve as electrical conductive pads.

7. The method for fabricating the circuit board structure of claim 1, wherein the filling material is protruded from the plated through hole, and can be leveled with the metal layer formed on the surface of the core layer by a brush polishing process.

8. The method for fabricating the circuit board structure of claim 1, wherein the core layer is a resin coated copper (RCC) film.

9. The method for fabricating the circuit board structure of claim 1, wherein the core layer is a multi-layered circuit board completed with initial processes, and the multi-layered circuit board is laminated with an insulating layer having a metal layer on a surface thereof.

10. A circuit board structure, comprising of:
a core layer having at least one through hole;
a circuit layer formed on the surface of the core layer, wherein a plated through hole is formed in the through hole of the core layer to electrically connect circuit layers formed on the surface of the core layer; and
a filling material for filling the plated through hole, wherein the filling material is positioned lower than the circuit layer.

11. The circuit board structure of claim 10, further comprising a circuit build-up structure formed on the surface of the core layer and the circuit layer.

12. The circuit board structure of claim 11, wherein the circuit build-up structure further comprises a dielectric layer, a circuit layer deposited on the dielectric layer, and a conductive structure formed in the dielectric layer.

13. The circuit board structure of claim 12, wherein the conductive structure is electrically connected to the circuit layer formed on the surface of the core layer.

14. The circuit board structure of claim 13, further comprising an insulating protective layer formed on an outside surface of the circuit build-up structure.

15. The circuit board structure of claim 14, wherein the insulating protective layer is formed with a plurality of openings to expose parts of the circuit layer which can serve as electrical conductive pads.

16. The circuit board structure of claim 10, wherein the core layer is a resin coated copper (RCC) film.

17. The circuit board structure of claim 10, wherein the core layer is a multi-layered circuit board completed with initial processes, and the multi-layered circuit board is laminated with an insulating layer having a metal layer on a surface thereof.
